(19) United States
(12) Patent Application Publication
(10) Pub. No.: US 2013/0105975 A1
(43) Pub. Date: May 2, 2013

(54) SEMICONDUCTOR CHIP DEVICE WITH THERMAL INTERFACE MATERIAL FRAME

(71) Applicants: Rafiqul Hussain, Fremont, CA (US); Edward S. Alcid, Sunnyvale, CA (US)

(72) Inventors: Rafiqul Hussain, Fremont, CA (US); Edward S. Alcid, Sunnyvale, CA (US)

(21) Appl. No.: 13/282,310

(22) Filed: Oct. 26, 2011

(51) Int. Cl. H01L 23/48; H01L 21/50

(52) U.S. Cl. 257/741; 438/106; 257/734; 257/E21.499; 257/E23.01

(57) ABSTRACT

Various semiconductor chip devices and methods of assembling the same are disclosed. In one aspect, a method of manufacturing is provided that includes coupling a frame to a surface of a substrate. The surface of the substrate is adapted to hold a first semiconductor chip that includes an upper surface. The frame includes an internal wall that is adapted to engage plural sidewalls of the first semiconductor chip. A portion of the internal wall and at least a portion of the upper surface are adapted to define an internal space.

### BACKGROUND OF THE INVENTION

1. Field of the Invention

This invention relates generally to semiconductor processing, and more particularly to semiconductor chip devices with thermal interface materials and methods of assembling the same.

2. Description of the Related Art

The thermal management of semiconductor chip devices, such as packaged semiconductor chips, often involves the placement of a thermal interface material on a principal surface of the semiconductor chip and the subsequent placement of a heat spreader on the thermal interface material. Conventionally, the thermal interface material is simply applied to the exposed surface of the semiconductor chip without any lateral constraints. The typically high viscosities of commonly used thermal interface materials, such as thermal pastes and thermal grease, is normally sufficient to hold the materials in position prior to the placement of a heat spreader. However, the placement of the heat spreader often involves application of significant pressure to the principal surface of the semiconductor chip. This can result in the thermal interface material being squeezed out laterally. If the mating surfaces of the thermal interface material and the heat spreader are less than planar or if the application of force is inconsistent across the face of the semiconductor chip, then the squeeze out can be asymmetric and produce thin spots in the thermal interface material.

Since thermal interface materials are typically exposed to elevated temperatures for prolonged periods during device operation, their lifespans may be limited by thermally-induced structural breakdown. In circumstances where the thickness of the thermal interface material is less than optimal due to squeeze out or asymmetrical loading, this life span may be shorter than desired. Less than optimal thickness consistency can also lead to higher than desired thermal resistance at various locations on the semiconductor chip.

Some conventional semiconductor chip thermal management systems utilize solder thermal interface materials. Indium is one such example. Indium exhibits favorable thermal properties. However, certain types of circuit boards or package substrates include surface mounted devices, such as passive components, that are subject to shorts in the event that excess indium migrates beyond the upper surface of a semiconductor chip.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes coupling a frame to a surface of a substrate. The surface of the substrate is adapted to hold a first semiconductor chip that includes an upper surface. The frame includes an internal wall that is adapted to engage plural sidewalls of the first semiconductor chip. A portion of the internal wall and at least a portion of the upper surface are adapted to define an internal space.

In accordance with another aspect of an embodiment of the present invention, a method of manufacturing is provided that includes coupling a frame to a surface of a semiconductor chip. The frame includes an internal wall. The internal wall and at least a portion of the surface define an internal space.

In accordance with another aspect of an embodiment of the present invention, an apparatus is provided that includes a substrate that has a surface adapted to hold a first semiconductor chip. The first semiconductor chip includes plural sidewalls and an upper surface. A frame is coupled to the surface by dispensing a polymeric material in a form that is positioned on the surface and hardening the polymeric material. The frame includes an internal wall adapted to engage the plural sidewalls. A portion of the internal wall and at least a portion of the upper surface are adapted to define an internal space.

In accordance with another aspect of an embodiment of the present invention, an apparatus is provided that includes a substrate that has a surface adapted to hold a first semiconductor chip. The first semiconductor chip includes plural sidewalls and an upper surface. A frame is coupled to the surface and includes an internal wall adapted to engage the plural sidewalls. A portion of the internal wall and at least a portion of the upper surface are adapted to define an internal space.

In accordance with another aspect of an embodiment of the present invention, an apparatus is provided that includes a semiconductor chip that has a surface. A frame is coupled to the surface and includes an internal wall. The internal wall and at least a portion of the surface defines an internal space.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a semiconductor chip device;

FIG. 2 is a sectional view of FIG. 1 taken at section 2-2;

FIG. 3 is a sectional view depicting exemplary mounting of a semiconductor chip on an exemplary substrate;

FIG. 4 is a sectional view like FIG. 3, but depicting an exemplary application of a frame to the substrate;

FIG. 5 is a sectional view like FIG. 4, but depicting the exemplary frame following application;

FIG. 6 is a sectional view like FIG. 4, but depicting an alternate exemplary application of a frame;

FIG. 7 is a sectional view like FIG. 6, but depicting exemplary mounting of a semiconductor chip to the substrate;

FIG. 8 is a plan view of the frame depicted in FIG. 7;

FIG. 9 is a sectional view depicting another alternate exemplary application of a frame to a substrate;

FIG. 10 is a sectional view depicting exemplary application of a thermal interface material to an internal space defined in part by an exemplary frame;

FIG. 11 is a sectional view like FIG. 10 but depicting exemplary mounting of an exemplary heat spreader;

FIG. 12 is a sectional view depicting an alternate exemplary embodiment of a semiconductor chip device incorporating multiple stacked semiconductor chips;

FIG. 13 is a pictorial view of an exemplary embodiment of a semiconductor chip device;

FIG. 14 is a pictorial view of an exemplary substrate configured as a semiconductor wafer; and

FIG. 15 is a pictorial view of an exemplary semiconductor chip device engaged by an exemplary pick and place mechanism.

### DETAILED DESCRIPTION OF SPECIFIC EMBODIMENTS

Various embodiments of a semiconductor chip device are disclosed. One arrangement includes a semiconductor chip mounted on a substrate and circumscribed by a frame that, along with a portion of an upper surface of the semiconductor chip, defines an internal space that may be used to hold a volume of thermal interface material. The frame can act as a load member to prevent a heat spreader from squeezing out the thermal interface material. In another arrangement, the frame may be mounted on the upper surface of the semiconductor chip to provide an internal space that again may be used to hold a thermal interface material. Additional details will now be described.

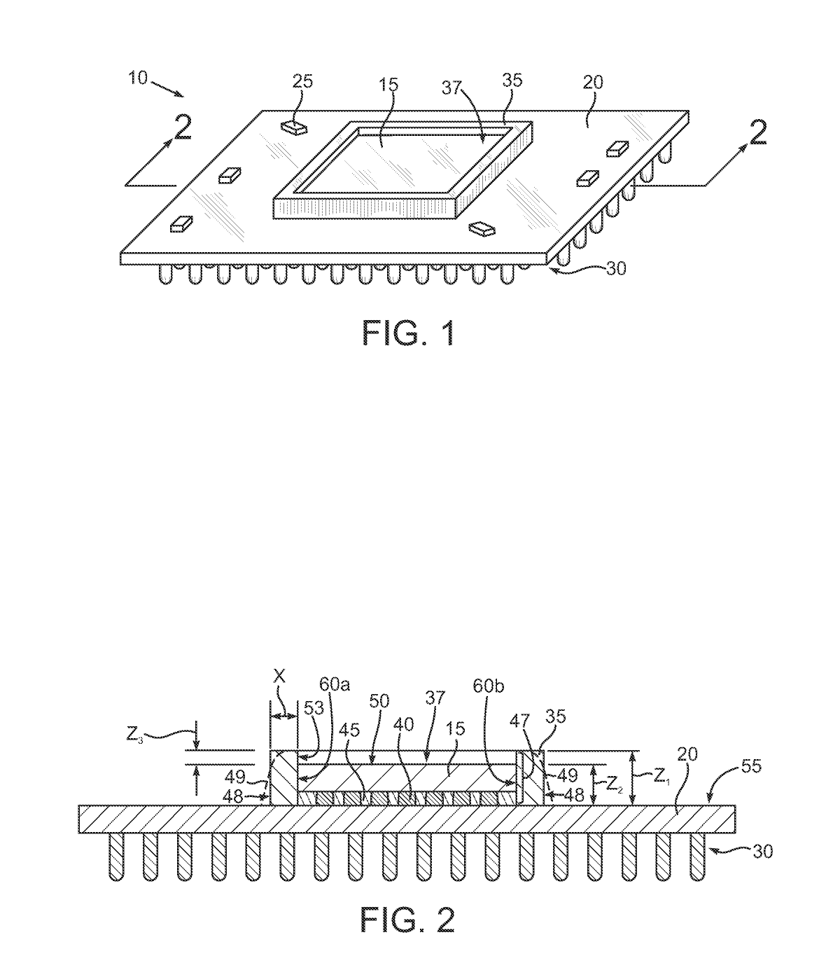

In the drawings described below, reference numerals are generally repeated where identical elements appear in more than one figure. Turning now to the drawings, and in particular to FIG. 1 is a pictorial view of an exemplary embodiment of a semiconductor chip device 10 that includes a semiconductor chip 15 mounted on a substrate 20. The exemplary embodiments disclosed herein are not dependent on particular implementations of either the semiconductor chip 15 or the substrate 20. Thus, the semiconductor chip 15 may be any of a myriad of different types of circuit devices used in electronics, such as, for example, microprocessors, graphics processors, combined microprocessor/graphics processors, application specific integrated circuits, memory devices or the like, and may be single or multi-core or even stacked with additional dice. Furthermore, the semiconductor chip 15 could be configured as an interposer with or without some logic circuits. Thus, the term “chip” includes an interposer and vice versa. The semiconductor chip 15 may be constructed of bulk semiconductor, such as silicon or germanium, or semiconductor on insulator materials, such as silicon-on-insulator materials, or even other types of materials. The semiconductor chip 15 may be flip-chip mounted to the substrate 20 and electrically connected thereto by interconnect structures shown in subsequent figures.

The substrate 20 may be an interposer, a semiconductor chip package substrate, a circuit card, or virtually any other type of printed circuit board. A monolithic structure or a build-up design could be used for the substrate 20. For example, a build-up design may consist of a central core upon which one or more build-up layers are formed and below which an additional one or more build-up layers are formed. The core itself may consist of a stack of one or more layers. One example of such an arrangement may be termed a so called “2-2-2” arrangement where a single-layer core is laminated between two sets of two build-up layers. If implemented as a semiconductor chip package substrate, the number of layers in the substrate 20 can vary from four to sixteen or more, although less than four may be used. So-called “coreless” designs may be used as well. The layers of the circuit board 20 may consist of an insulating material, such as various well-known epoxies, interspersed with metal interconnects. A multi-layer configuration other than buildup could be used. Optionally, the circuit board 20 may be composed of well-known ceramics or other materials suitable for package substrates or other printed circuit boards. The substrate 20 may be populated with various top-mounted components 25, which may be passive components such as capacitors, inductors and/or resistors or active components such as integrated circuits. The substrate 20 is provided with a number of conductor traces and vias and other structures in order to provide power, ground and signals transfers between the semiconductor chip 15 and another circuit device that is not shown. To facilitate those transfers, the substrate 20 may be provided with input/outputs, depicted in this illustrative embodiment as a pin grid array 30. However, the skilled artisan will appreciate that land grid arrays, ball grid arrays or other types of interface structures may be used as desired. The semiconductor chip device 10 includes a frame 35 that is seated on the substrate 20 and circumscribes the semiconductor chip 15. The frame 35 projects above the upper surface of the semiconductor chip 15 to define an internal space 37 that is operable to hold a thermal interface material to be shown in subsequent figures.

Additional details of the semiconductor chip device 10 may be understood by referring now also to FIG. 2, which is a sectional view of FIG. 1 taken at section 2-2. In this illustrative embodiment, the semiconductor chip 15 is flip-chip mounted to the substrate 20 and electrically connected thereto by way of plural solder joints 40. Optionally, other types of interconnect structures such as conductive pillars with or without solder enhancement or other types may be used as desired. To lessen the effects of differences in the coefficients of thermal expansion of the semiconductor chip 15, the substrate 20 and the solder joints 40, an underfill material 45 may be positioned between the semiconductor chip 15 and the substrate 20. The substrate 20 may include plural conductive traces or other types of conductors that establish ohmic pathways between the individual pins of the pin grid array 30 and the solder joints 40 that are not shown for simplicity of illustration. The frame 35 may be sized so that an internal wall 47 engages the sidewalls 60a and 60b (and the other two sidewalls not shown in FIG. 2) of the semiconductor chip 15, preferably with a snug fit. The frame 35 may be fabricated with substantially vertical external sidewalls 48, sloped external sidewalls 49 (shown in dashed) or even other profiles. The frame 35 is advantageously fabricated with a height z₁ that exceeds the elevation z₂ of the upper surface 50 of the semiconductor chip 15 relative to an upper surface 55 of the substrate 20. This yields the internal space 37 defined by the upper surface 50 of the semiconductor chip 15 and the portion 53 of the internal wall 47 of the frame 35 that projects above the upper surface 50 with a height z₃=zᵣ−z₂. The desired values for z₁ and z₃ will depend upon prevailing device geometries. In an exemplary embodiment, the value for z₃ may be on the order of 0.2 to 0.9 mm. The width x of a wall of the frame 35 may be on the order of 0.3 to 2.0 mm. The width x may be about the same range, albeit variable with elevation, if the sloped external sidewalls 49 are used. Again this value will depend upon prevailing device geometries. Here, the internal space 37 is coextensive with the upper surface 50 of the semiconductor chip 15. However, the frame 35 could be fabricated with an overhang (not shown) that projects over a portion of the upper surface 50 and thus the internal space 37 could be less than completely coextensive laterally with the upper surface 50. In this way, the internal space 37 may be defined by at least a portion of the upper surface 50. As described more fully below, a variety of thermal interface materials (not depicted in FIG. 2) may be positioned in the internal space 37 to facilitate the thermal management of a semiconductor chip 15.

The frame 35 is advantageously fabricated from insulating materials that can undergo elastic or plastic deformation when loads are applied by a heat spreader or other device. If a formless application process is used, then materials with sufficient viscosity to avoid excessive lateral creep prior to cure are desirable. A variety of materials may be used, such as epoxies with or without various types of fillers, such as silica, or other polymeric materials.

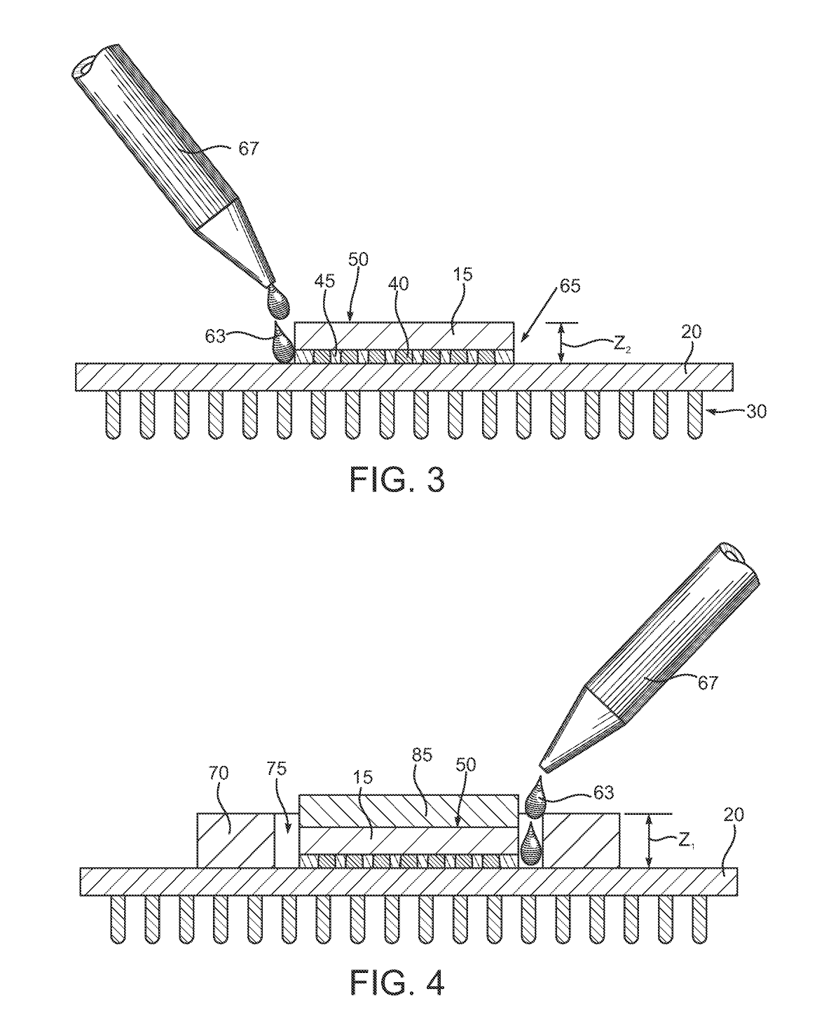

Exemplary methods for assembling the semiconductor chip device 10, including the frame 35 thereof, may be understood by referring now to FIGS. 3, 4 and 5, and initially to FIG. 3. FIG. 3 depicts the semiconductor chip device 10 in section, following the flip-chip mounting of the semiconductor chip 15 to the substrate 20, a solder reflow to establish the solder joints 40 and the application of the underfill material 45. In addition, the pins of the pin grid array 30 have been secured to the substrate 20. These preliminary assembly processes may be performed using well-known processes for fabricating and manipulating circuit boards and flip-chip mounting semiconductor devices thereto. As noted above, the upper surface 50 of the semiconductor chip 15 will have some elevation z₂ relative to the upper surface 55 of the substrate 20. This value z₂ will depend on the thickness of the semiconductor chip 15 as well as the heights of the solder joints 40 post reflow.

A formless application process may be used at this stage to form the frame 35 shown in FIG. 2. A suitable polymeric material 63 may be applied around the perimeter 65 of the semiconductor chip 15 by an applicator 67. Gravity will tend to disperse the material 63. However, the combination of surface tension and the selection of a sufficiently high viscosity for the material 63 should prevent the material 63 from flowing away substantially from the perimeter 65. The polymeric material 63 may be cured at this stage by a variety of stimuli. Depending on the composition of the polymeric material, heat, light or other stimuli may be used to cure and harden the polymeric material. If the polymeric material 63 will self-harden just due to chemical reactions between two or more constituents, then no external stimulus need be applied. In an exemplary embodiment, a thermal cure at about 100° C. for about one hour may be performed. Such a formless application process may be suitable where sloped external sidewalls (see 49 in FIG. 2) are desired or where high precision in frame geometry is not critical.

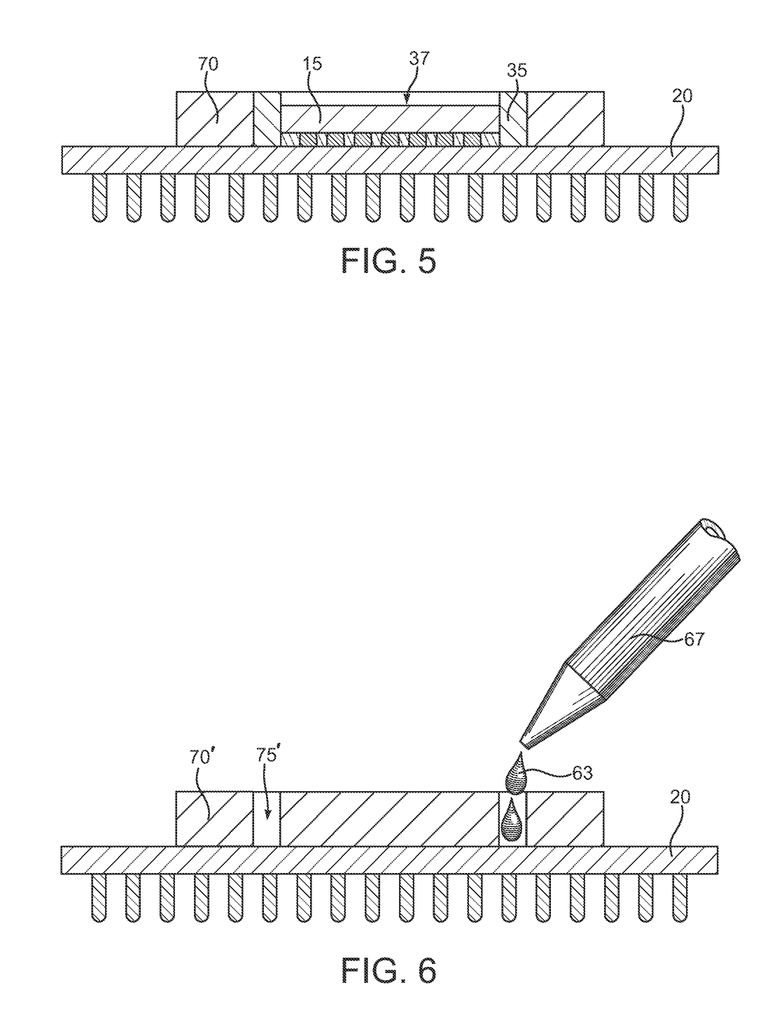

An exemplary frame application process that does use a form may be understood by referring now to FIGS. 4 and 5. As shown in FIG. 4, a suitable form 70 may be positioned on the substrate 20. The form 70 has an internal cavity 75 with a footprint designed to yield the desired footprint of the frame 30 depicted in FIGS. 1 and 2. Note that the form 70 may be fabricated so that the internal space or cavity 75 has a height z₁ to yield the desired ultimate height z₁ of the frame 35. With the form 70 in place, a suitable polymeric material 63 may be introduced into the internal cavity 75 by a suitable applicator 80. Gravity and capillary force may be used to disperse the polymeric material 63. Optionally, molding may be used wherein the internal space 75 is sealed, but for one or more fill apertures (not shown), and a molding process used to introduce the polymeric material 63. Prior to introducing the polymeric material 63, a suitable mask 85 should be placed on the upper surface 50 of the semiconductor chip 15 to prevent the polymeric material 63 from flowing over the upper surface. The polymeric material 63 may have strong adhesive properties, which can complicate later removal of the form 70. Accordingly, the form 70 may be fabricated from (or the internal cavity 75 at least coated with) a material that resists bonding with polymers. The mask 85 should be similarly constructed so that subsequent removal is facilitated. Exemplary materials include polytetrafluoroethylene, perfluoroalkoxy, fluorinated ethylene propylene, or even well-known greases or oils.

The polymeric material 63 may be cured at this stage by a variety of stimuli. Depending on the composition of the polymeric material, heat, light or other stimuli may be used to cure and harden the polymeric material. If the polymeric material 63 will self-harden just due to chemical reactions between two or more constituents, then no external stimulus need be applied. In an exemplary embodiment, a thermal cure at about 100° C. for about one hour may be performed. Following the hardening of the polymeric material 63, the mask 85 is removed to leave the internal space 37 as shown in FIG. 5. At this stage, the frame 35 may be removed to yield the frame 35 that circumscribes the semiconductor chip 15 as shown in FIG. 2.

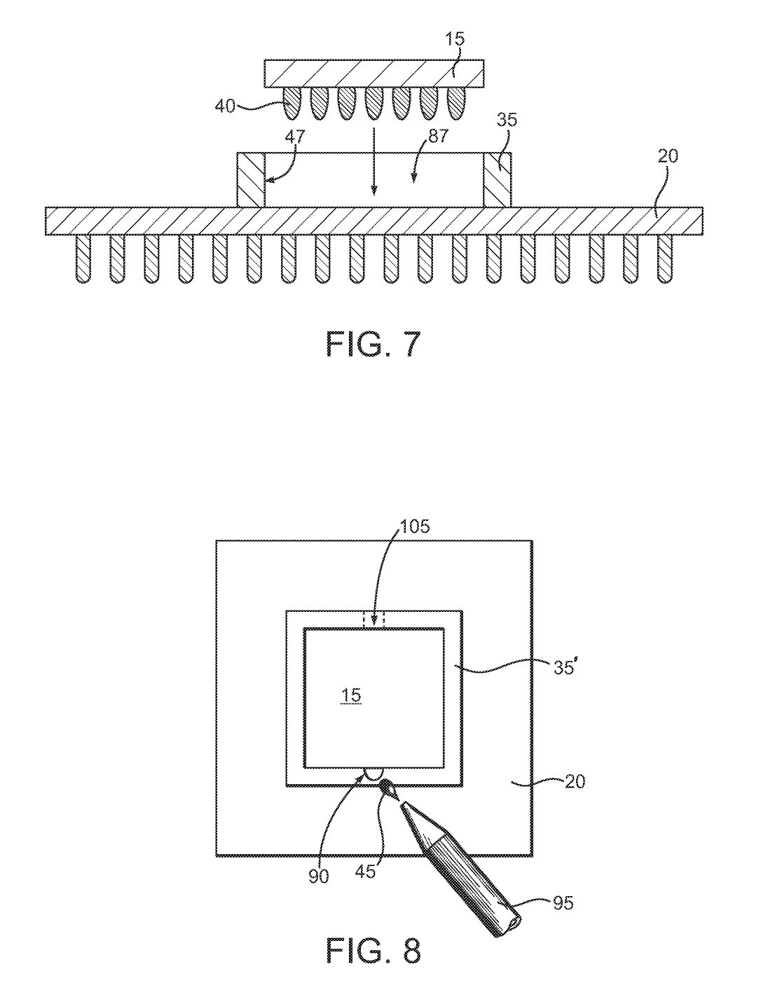

In the foregoing illustrative embodiment, the placement of the semiconductor chip 15 on the substrate 20 precedes the application of the polymeric frame 35. However, and as depicted in FIGS. 6 and 7, the process sequence may be performed in reverse order where application of the frame 35 may precede the mounting of the semiconductor chip 15. Thus, and as shown in FIG. 6, which is a sectional view of the substrate 20, a suitable form 70′ may be positioned on the substrate 20 and the polymeric material 63 may be introduced into an interior space 75′, which has the desired footprint of the frame 35 to be formed. Again, the applicator 67 may be used in conjunction with gravity and capillary action or a molding process may be used as well. Like the form 70 depicted in FIGS. 4 and 5, the form 70′ should be constructed of materials that resist bonding with polymers. Exemplary materials include polytetrafluoroethylene, perfluoroalkoxy, fluorinated ethylene propylene, or even well-known greases or oils. Following the dispensing and curing of the polymeric material 63, the form 70′ depicted in FIG. 6 may be removed to yield the frame member 35 as shown in FIG. 7. Here, the frame 35 is formed with an internal space 87, which has a footprint appropriately sized so that the internal wall 47 will engage the corresponding sidewalls 60a and 60b (and the other two sidewalls not shown in FIG. 7) of the semiconductor chip 15. Next, the semiconductor chip 15 may be dropped into the internal space 87 of the frame 35 and mounted to the substrate 20 and a reflow may be performed as necessary in order to secure the solder joints 40.

Because the application of the frame 35 precedes the mounting of the semiconductor chip 15 in this illustrative embodiment, precautions may need to be taken in order to facilitate the ultimate application of the underfill material 45 depicted in FIGS. 1, 2 and 3. This may be accomplished in a variety of ways. As shown in FIG. 8, which is a plan view of an exemplary frame 35′ positioned on the substrate 20, the frame 35′ may be provided with a fill port or slot 90. The underfill 45 may be introduced into the slot 90 by a suitable applicator 100. Capillary action may take the underfill 45 beneath the semiconductor chip 15. In another option, a suitable lateral opening 105 (depicted in phantom) in a wall of the frame 35′ may be used to introduce the underfill 45 where it can flow beneath the semiconductor chip 15.

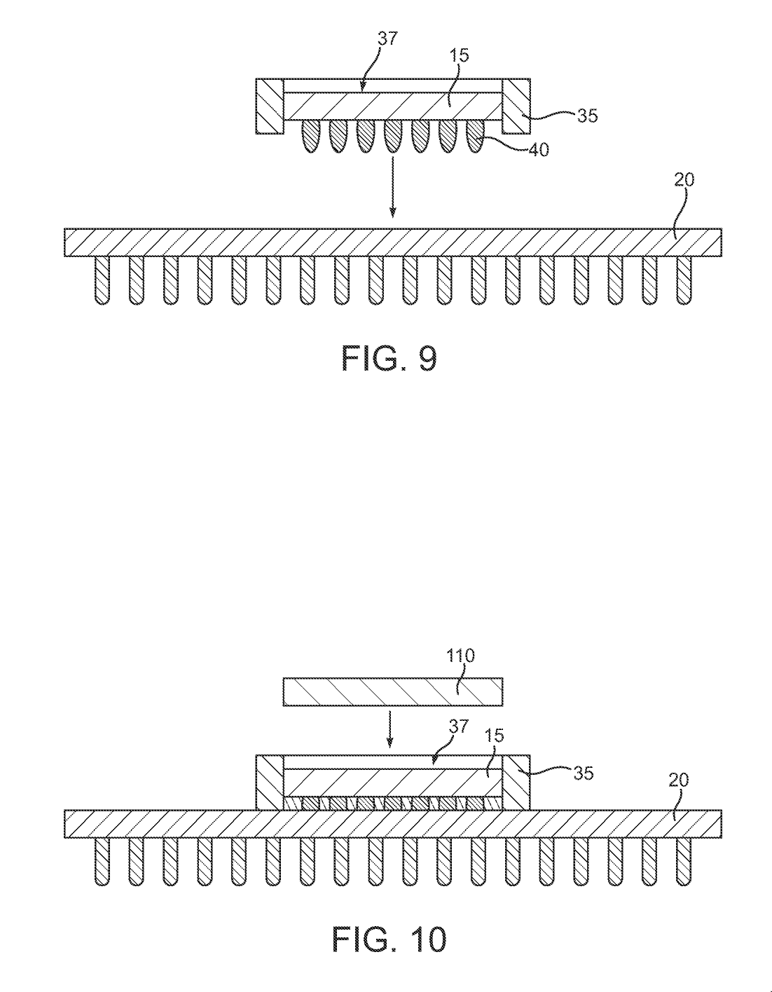

In still another alternate exemplary embodiment, the frame 35 and the semiconductor chip 15 may be simultaneously mounted to the substrate 20 as shown in FIG. 9. Here, the frame 35 may be fabricated using the techniques disclosed herein and thereafter secured to the semiconductor chip 15 or may be fabricated around the semiconductor chip 15 prior to the semiconductor chip 15 being connected to the substrate 20. Thereafter, the combination of the semiconductor chip 15 and the frame 35 may be positioned on the substrate 20 and a suitable reflow performed as necessary to metallurgically bond the solder joints 40 to the substrate 20. Here, the internal space 37 may serve as a vessel to hold various types of thermal interface materials (not visible in FIG. 9) to be described below.

As just noted, the internal space 37 of any of the disclosed embodiments of the frame 35, 35′ may be used to as a vessel to hold certain types of thermal interface materials. Attention is now turned to FIG. 10, which is a sectional view depicting the semiconductor chip 15 mounted to the substrate 20 with the frame 35 in position. It should be understood that the frame 35 may be fabricated and positioned on the substrate 20 using any of the techniques disclosed herein and indeed may be, for example, the frame member 35′ as well. Here, a thermal interface material 110 may be positioned in the interior space 37 and in thermal contact with the semiconductor chip 15. The thermal interface material 110 may take on a great variety of different forms, such as a thermal paste, a thermal grease, a liquid thermal interface material, a solder, such as indium with or without other metals, or even a solid metal thermal plate composed of copper, aluminum, gold, nickel, combinations of these or other materials. One benefit associated with the frame 35 and the internal space 37 is that, regardless of the particular composition, the thermal interface material 110 is constrained from seeping out laterally following positioning in the internal space 37 even if compressed or otherwise pressured by a heat spreader (not visible in FIG. 10) or other mechanism. Thus, the thermal interface material 110 may exhibit a greater lifespan and, if in malleable form, be applied with a more consistent thickness.

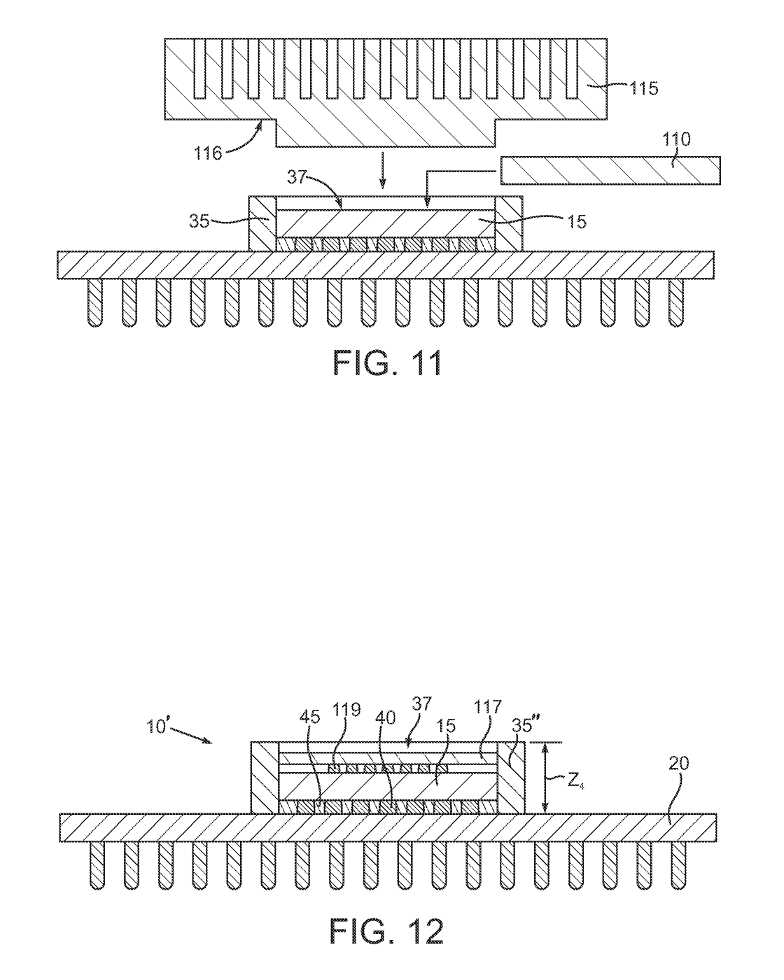

A variety of different types of heat spreaders may be positioned on the semiconductor chip 15 while taking advantage of the presence of the frame 35. For example, and as shown in FIG. 11, a suitable heat spreader 115 may be positioned in thermal contact with the semiconductor chip 15. If desired, the thermal interface material 110 of the type described above may be positioned in the internal space 37 in thermal contact with the semiconductor chip 15 prior to the placement of the heat spreader 115. The heat spreader 115 may take on a huge variety of different configurations, such as semiconductor chip package lids, heat sinks, heat pipes, heat exchangers or others to name just a few. The heat spreader 115 may be configured with a surface 116 designed to seat on the frame 35. In that event, the heat spreader 115 will still establish thermal contact with either the semiconductor chip directly or via the thermal interface material 110, but the frame 35 will take most if not all of the compressive mechanical load. In this way, squeeze out of the thermal interface material 110 is avoided and compressive stress on the semiconductor chip 15 is reduced.

Any of the disclosed frames 35, 35′ may be used with stacked dice arrangements. FIG. 12 is a sectional view of an alternate exemplary embodiment of a semiconductor chip device 10′, which may be substantially similar to the semiconductor chip device 10 shown in FIGS. 1 and 2, and thus include the semiconductor chip 15 mounted on the substrate 20 and connected by the solder joints 40, and an underfill 45. Here, however, an alternate exemplary frame 35″ may be fabricated and used as generally described elsewhere herein, but with a height z₄ that is large enough to accommodate another semiconductor chip 117 stacked on the semiconductor chip 15 and still yield the desired internal space 37. The semiconductor chip 117 may be electrically connected to either the semiconductor chip 15 and/or the substrate 20 by interconnects 119, which may be microbumps, pillars or other conductor structures. If desired, additional semiconductor chips (not shown) may be stacked on the semiconductor chip 15.

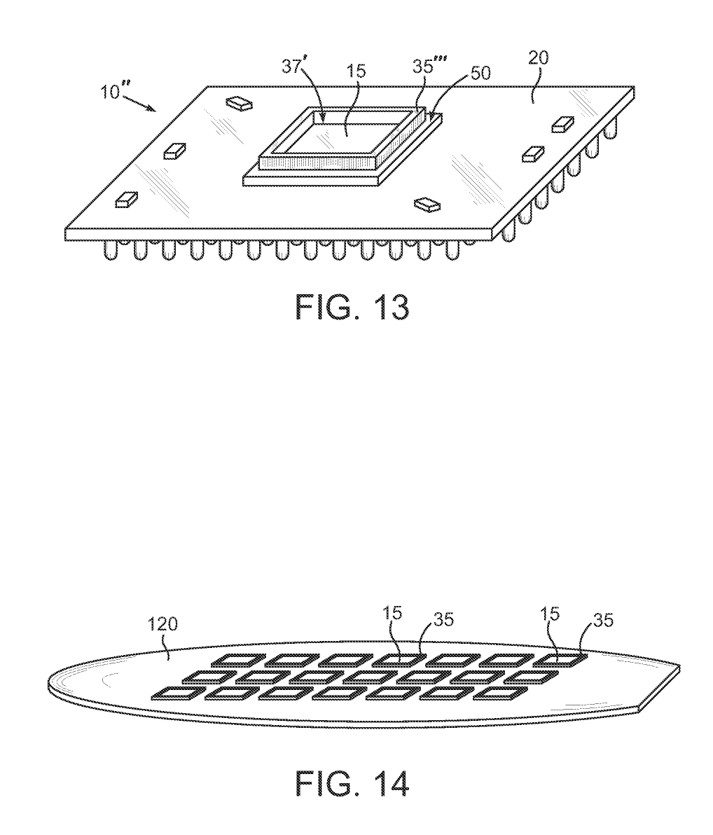

In the foregoing disclosed embodiments, the frame 35, 35′ is formed or otherwise applied around the perimeter of the semiconductor chip 15. However, in an alternate exemplary embodiment, the benefits of using the frame to at least partially define an internal space that is operable to hold a thermal interface may be obtained by forming or otherwise placing a frame on top of a semiconductor chip. In this regard, attention is now turn to FIG. 13, which is a pictorial view of an alternate exemplary embodiment of a semiconductor chip device 10″ that may include the semiconductor chip 15 mounted on the substrate 20 as generally described above. Here, however, an alternate exemplary frame 35″ may be formed or otherwise mounted on the upper surface 50 of the semiconductor chip 15. The frame 35″ again defines an internal space 37′ that may be used to hold a thermal interface material (not shown) or provide another function. The internal space 37″ will have a footprint that is smaller than the footprint of the semiconductor chip 15. Note that the frame 35″ may be formed or otherwise applied using the techniques described elsewhere herein.

It should be understood that any of the disclosed embodiments of the frame 35, 35′, etc. may be arranged with a semiconductor chip 15 singly or on en masse. For example, and as shown in FIG. 14, which is a pictorial view of a semiconductor substrate 120, plural frame members 35 may be fabricated or otherwise positioned around semiconductor chips 15 that are mounted on the substrate 120. Here, the substrate 120 may be a semiconductor wafer so that following singulation, the semiconductor chips 15 and their corresponding frames 35 will be mounted to what will function as a semiconductor interposer or a circuit board, in strip form or otherwise, that may be ultimately singulated into individual circuit boards with chips 15 mounted thereon.

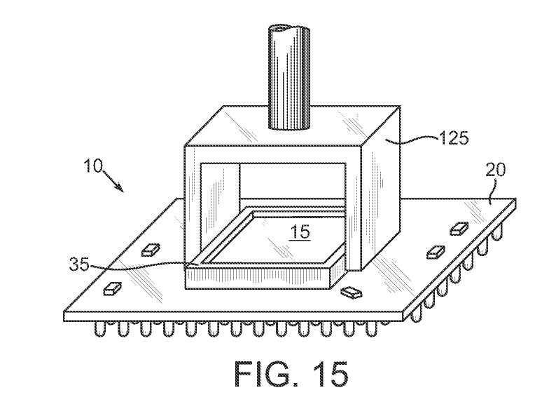

In addition to serving as a vessel to laterally constrain a thermal interface material, any of the disclosed embodiments of the frame member 35, 35′, 35″, 35″′ etc. may serve another role, namely, to facilitate the safe handling of a semiconductor chip. In this regard, attention is turned to FIG. 15, which is a pictorial view of the semiconductor chip device 10. Here, the frame 35 serves as a protective wall that surrounds the semiconductor chip 15. Thus, a pick and place device 125 may be used to physically engage the frame 35 to pick and place the semiconductor chip device 10. The pick and place device 125 may be part of a larger machine (not shown) designed to perform one or more functions, and be moveable by hydraulic, pneumatic or electrical mechanisms. In this way, the semiconductor chip device 10 may be moved from one location to another without having to physically contact either the substrate 20 or the semiconductor chip 15. Of course, the same types of physical manipulations may be performed by human operator as well, again with the benefit that the semiconductor chip 15 and the substrate 20 need not be actually touched during the movement.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
coupling a frame to a surface of a substrate, the surface adapted to hold a first semiconductor chip that includes an upper surface, the frame including an internal wall adapted to engage plural sidewalls of the first semiconductor chip, a portion of the internal wall and at least a portion of the upper surface adapted to define an internal space.

2. The method of claim 1, wherein the coupling the frame comprises molding a polymeric material.

3. The method of claim 1, comprising coupling the first semiconductor chip to the surface.

4. The method of claim 3, comprising coupling the first semiconductor chip to the surface before the frame.

5. The method of claim 3, comprising coupling the first semiconductor chip after the frame.

6. The method of claim 3, comprising coupling a second semiconductor chip between the first semiconductor chip and the surface of the substrate.

7. The method of claim 3, comprising placing a thermal interface material in the internal space.

8. The method of claim 1, comprising engaging the frame with a pick and place mechanism to move the substrate.

9. The method of claim 1, wherein the substrate comprises a semiconductor wafer.

10. A method of manufacturing, comprising:
coupling a frame to a surface of a semiconductor chip, the frame including an internal wall, the internal wall and at least a portion of the surface defining an internal space.

11. An apparatus, comprising:
a substrate having a surface adapted to hold a first semiconductor chip, the first semiconductor chip including plural sidewalls and an upper surface; and
coupling a frame coupled to the surface by dispensing a polymeric material in a form positioned on the surface and hardening the polymeric material, the frame including an internal wall adapted to engage the plural sidewalls, a portion of the internal wall and at least a portion of the upper surface adapted to define an internal space.

12. The apparatus of claim 11, comprising the first semiconductor chip coupled to the surface of the substrate, the portion of the internal wall and at least a portion of the upper surface of the first semiconductor chip defining the internal space.

13. The apparatus of claim 12, comprising a thermal interface material in the internal space.

14. The apparatus of claim 12, comprising a second semiconductor chip positioned between the first semiconductor chip and the surface of the substrate.

15. An apparatus, comprising:
a substrate having a surface adapted to hold a first semiconductor chip, the first semiconductor chip including plural sidewalls and an upper surface; and
a frame coupled to the surface and including an internal wall adapted to engage the plural sidewalls, a portion of the internal wall and at least a portion of the upper surface adapted to define an internal space.

16. The apparatus of claim 15 comprising the first semiconductor chip coupled to the surface of the substrate, the portion of the internal wall and at least a portion of the upper surface of the first semiconductor chip defining the internal space.

17. The apparatus of claim 16, comprising a thermal interface material in the internal space.

18. The apparatus of claim 16, comprising a second semiconductor chip positioned between the first semiconductor chip and the surface of the substrate.

19. The apparatus of claim 16, comprising a heat spreader in thermal contact with the first semiconductor chip.

20. The apparatus of claim 15, wherein the substrate comprises a circuit board.

21. The apparatus of claim 15, wherein the substrate comprises an interposer.

22. The apparatus of claim 15, wherein the substrate comprises a semiconductor wafer.

23. The apparatus of claim 15, wherein the frame comprises a polymeric material.

24. An apparatus, comprising:
a semiconductor chip having a surface; and
a frame coupled to the surface and including an internal wall, the internal wall and at least a portion of the surface defining an internal space.
